(19) United States
(12) Patent Application Publication
(10) Pub. No.: US 2023/0288809 A1
(43) Pub. Date: Sep. 14, 2023

(54) COMPOSITION FOR RESIST UNDERLAYER AND PATTERN FORMATION METHOD USING SAME

(71) Applicant: SAMSUNG SDI CO., LTD., Yongin-si, Gyeonggi-do (KR)

(72) Inventors: Yoojeong CHOI, Suwon-si (KR); Soonhyung KWON, Suwon-si (KR); Minsoo KIM, Suwon-si (KR); Seongjin KIM, Suwon-si (KR); Jaeyeol BAEK, Suwon-si (KR); Hwayoung JIN, Suwon-si (KR); Hyeon PARK, Suwon-si (KR); Shinhyo BAE, Suwon-si (KR); Daeseok SONG, Suwon-si (KR); Minki CHON, Suwon-si (KR)

(21) Appl. No.: 18/006,135

(22) PCT Filed: Nov. 11, 2021
(86) PCT No.: PCT/KR2021/016394

§ 371 Date: Jan. 19, 2023

(30) Foreign Application Priority Data
Nov. 20, 2020 (KR) 10-2020-0156824

(51) Int. Cl. G03F 7/11; C08G 75/045; C08F 26/06; G03F 7/38

(52) U.S. Cl. CPC G03F 7/11; C08G 75/045; C08F 26/06; G03F 7/38

(57) ABSTRACT

Provided are a resist underlayer composition including a polymer having a ring backbone including two or more nitrogen atoms in a ring, a compound represented by Chemical Formula 1, and a solvent; and a method of forming patterns using the resist underlayer composition:

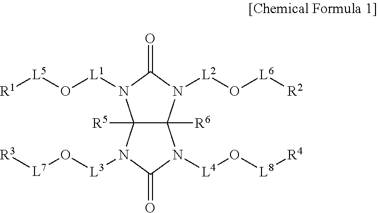

The definitions of Chemical Formula 1 are as described in the detailed description.

### TECHNICAL FIELD

This disclosure relates to a resist underlayer composition, and a method of forming patterns using the same.

### BACKGROUND ART

Recently, the semiconductor industry has developed to an ultra-fine technique having a pattern of several to several tens of nanometer size. Such ultrafine technique essentially needs effective lithographic techniques.

A lithographic technique is a processing method that includes coating a photoresist layer on a semiconductor substrate such as a silicon wafer to form a thin film, irradiating the photoresist layer with activating radiation such as ultraviolet rays through a mask pattern on which the device pattern is drawn, developing the resultant to obtain a photoresist pattern, and etching the substrate using the photoresist pattern as a protective layer to form a fine pattern corresponding to the pattern, on the surface of the substrate.

Exposure performed during formation of the photoresist pattern is one of important factors for obtaining a photoresist image with a high resolution.

As ultrafine pattern manufacturing technology is required, short wavelengths such as i-line (a wavelength of 365 nm), KrF excimer laser (a wavelength of 248 nm), and ArF excimer laser (a wavelength of 193 nm) are used as activated radiation used for exposure of photoresists. Accordingly, in order to solve problems caused by diffuse reflection or standing wave from the semiconductor substrate of the activated radiation, many studies have been made to solve the problem by interposing a resist underlayer having an optimized reflectance between the resist and the semiconductor substrate.

On the other hand, in addition to the activated radiation, a method of using high energy rays such as EUV (extreme ultraviolet; a wavelength of 13.5 nm), E-Beam (electron beam), and the like as a light source for forming a fine pattern is also performed, and the corresponding light source has almost no reflection from a substrate, but as the pattern is refined, the resist underlayer should have a much thinner thickness, and in order to improve collapse of the formed pattern, research on improving the adhesion between the resist and the underlayer is also being widely studied. In addition, in order to maximize efficiency of the light source, research on sensitivity through the underlayer is also studied.

### DISCLOSURE

### Technical Problem

A resist underlayer composition, which does not cause a pattern collapse of the resist even in a fine patterning process, is formed into an ultra-thin film, so that an etching process time may be shortened, and improves crosslinking characteristics to improve coating uniformity, gap-fill characteristics, and resist pattern-forming capability, is provided.

Another embodiment provides a method of forming patterns using the resist underlayer composition.

### Technical Solution

A resist underlayer composition according to an embodiment includes a polymer having a ring backbone including two or more nitrogen atoms in a ring, a compound represented by Chemical Formula 1, and a solvent:

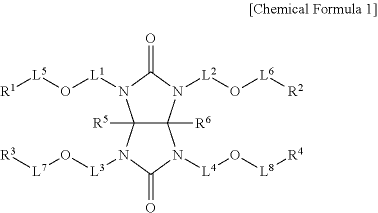

wherein, in Chemical Formula 1,
L¹ to L⁴, and L⁵ to L⁸ are each independently a single bond, a substituted or unsubstituted C1 to C10 alkylene group, a substituted or unsubstituted C3 to C20 cycloalkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, a halogen, a cyano group, an amino group, an epoxy group, a C1 to C10 alkoxy group, or a combination thereof, n and m are each independently an integer of 0 to 5, and * is a linking point), or a combination thereof,
R¹ to R⁴ are each independently a substituted or unsubstituted C1 to C10 aliphatic saturated or unsaturated hydrocarbon group, a substituted or unsubstituted C3 to C10 alicyclic saturated or unsaturated hydrocarbon group, a substituted or unsubstituted C2 to C10 saturated or unsaturated alicyclic heterohydrocarbon group, a substituted or unsubstituted C6 to C30 aromatic group, a substituted or unsubstituted C2 to C30 heteroaromatic group, a substituted or unsubstituted C1 to C10 alkoxy group, or a combination thereof,
when L⁵ to L⁸ are all single bonds or are all unsubstituted C1 to C10 alkylene groups, R¹ to R⁴ are all substituted or unsubstituted C1 to C10 aliphatic saturated or unsaturated hydrocarbon groups, or R¹ to R⁴ are not all substituted or an unsubstituted C1 to C2 alkoxy group, and
R⁵ and R⁶ are each independently hydrogen, deuterium, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, or a combination thereof.

In Chemical Formula 1, L¹ to L⁴, and L⁵ to L⁸ may each independently be a single bond, a substituted or unsubstituted C1 to C10 alkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, or a combination thereof, n and m are each independently an integer of 0 to 3, and * is a linking point), or a combination thereof, and
R¹ to R⁴ may each independently be a substituted or unsubstituted C1 to C10 alkyl group, a substituted or unsubstituted C2 to C10 alkenyl group including at least one double bond, a substituted or unsubstituted C3 to C10 cycloalkyl group, a substituted or unsubstituted C1 to C10 alkoxy group, or a combination thereof.

The compound represented by Chemical Formula 1 may include at least one compound represented by Chemical Formulas 4 to 11.

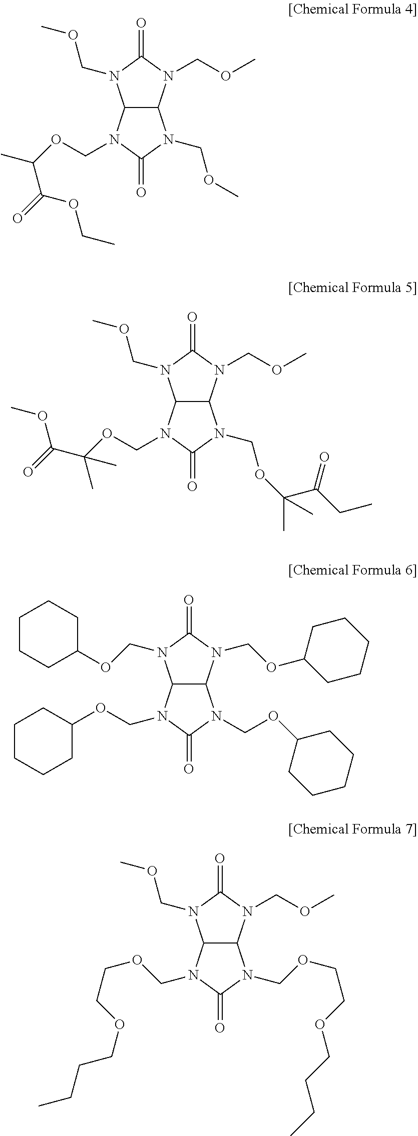

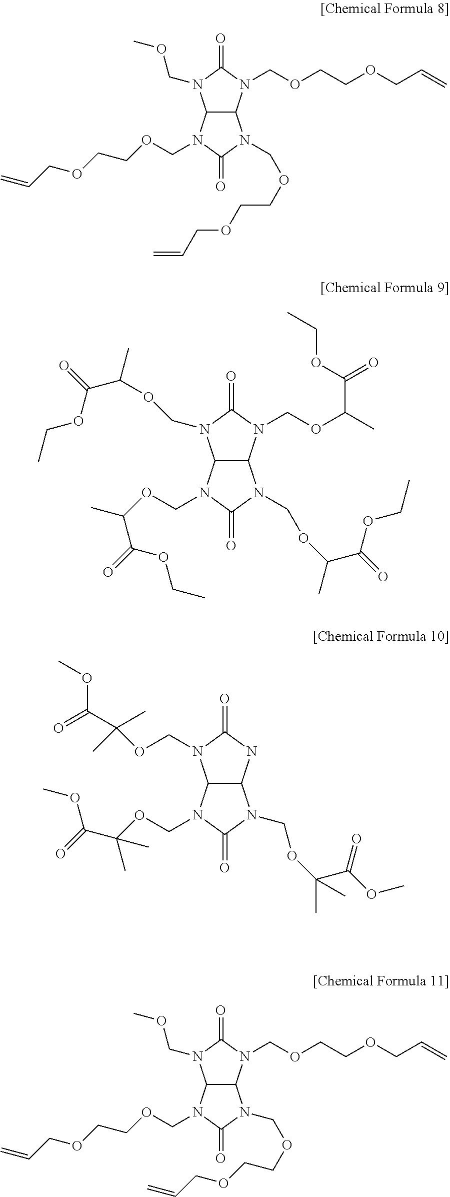

The polymer having the ring backbone including two or more nitrogen atoms in the ring may include at least one structure of Chemical Formulas A-1 to A-4.

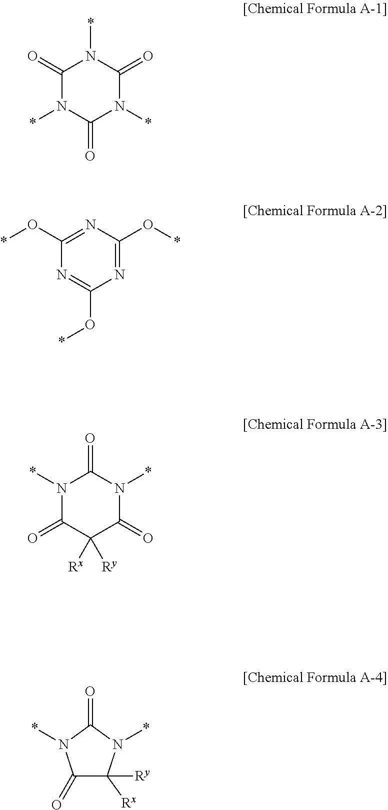

In Chemical Formulas A-1 to A-4,
R^{x} and R^{y} are each independently hydrogen, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof,
is each linking point in the polymer.

The polymer may include a structural unit represented by Chemical Formula 2, a structural unit represented by Chemical Formula 3, or a combination thereof:

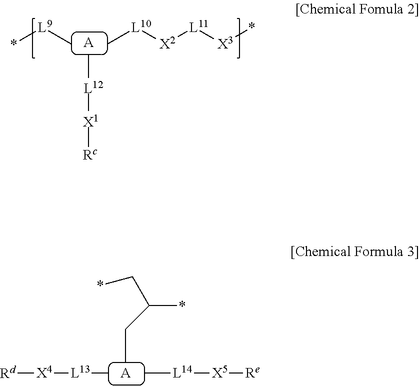

wherein, in Chemical Formulas 2 and 3,
A is a ring group including two or more nitrogen atoms in the ring,
R^{c}, R^{d}, and R^{e} are each independently a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof,
L⁹ to L¹⁴ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond, —O—, —S—, —S(═O)—, —S(═O)₂—, —C(═O)—, —(CO)O—, —O(CO)O—, —NR″″— (wherein, R″″ is hydrogen, deuterium, or a C1 to C10 alkyl group), or a combination thereof, and
is a linking point to the main chain or terminal end group of the polymer, respectively.

In Chemical Formulas 2 and 3,
R^{c}, R^{d}, and R^{e} may each independently be a substituted or unsubstituted C1 to C10 alkyl group, a substituted or unsubstituted C1 to C10 heteroalkyl group, or a combination thereof,
L⁹ to L¹³ may each independently be a single bond, a substituted or unsubstituted C1 to C10 alkylene group, a substituted or unsubstituted C1 to C10 heteroalkylene group, or a combination thereof, and
X¹ to X⁵ may each independently be a single bond, —O—, —S—, or a combination thereof.
A of Chemical Formulas 2 and 3 may be represented by at least one of Chemical Formulas A-1 to A-4, and
in Chemical Formulas A-1 and A-4,
indicates a linking point to any one of L⁹ to L¹⁴ in Chemical Formulas 2 and 3, or a side chain of the polymer, respectively.

The polymer may include any one of structural units represented by Chemical Formulas 12 to 21:

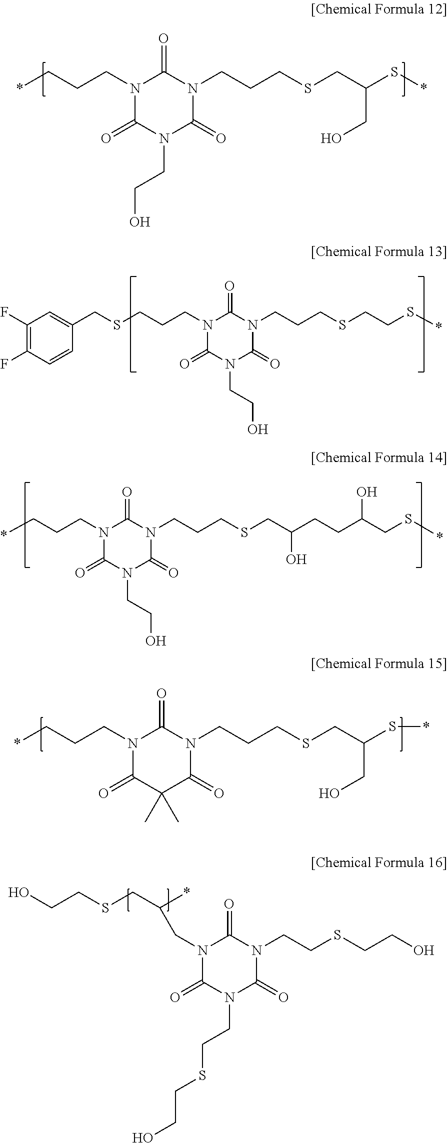

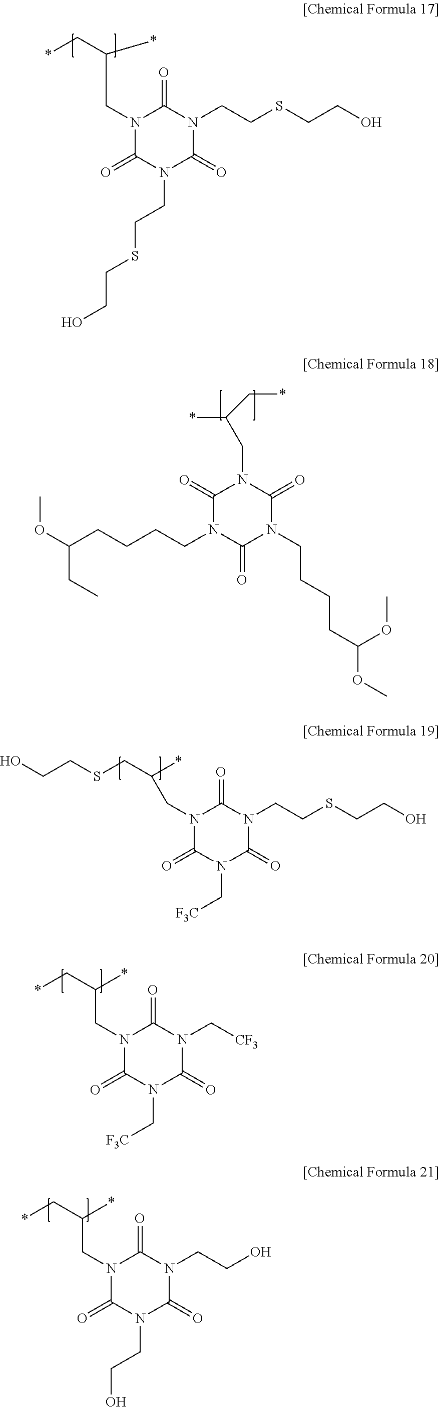

wherein, in Chemical Formulas 12 to 21,
is a linking point to the main chain, side chain, or terminal end group of the polymer.

The compound represented by Chemical Formula 1 may be included in an amount of 0.01 wt % to 5 wt % based on the total weight of the resist underlayer composition.

The polymer may have a weight average molecular weight of 2,000 g/mol to 300,000 g/mol.

The composition may further include one or more polymers selected from an acrylic resin, an epoxy resin, a novolac resin, a glycoluril resin, and a melamine resin.

The composition may further include an additive including a surfactant, a thermal acid generator, a plasticizer, a photoacid generator, a crosslinking agent, or a combination thereof.

Another embodiment provides a method of forming patterns that includes:
forming an etching target layer on a substrate,
forming a resist underlayer by applying the resist underlayer composition according to an embodiment on the etching target layer,
forming a photoresist pattern on the resist underlayer, and
sequentially etching the resist underlayer and the etching target layer using the photoresist pattern as an etching mask.

The forming of the photoresist pattern may include
forming a photoresist layer on the resist underlayer,
exposing the photoresist layer, and
developing the photoresist layer.

The forming of the resist underlayer may further include heat treatment at a temperature of 100° C. to 500° C. after coating the resist underlayer composition.

### Advantageous Effects

The resist underlayer composition according to an embodiment may form into an ultra-thin film for predetermined wavelengths such as EUV and the like and simultaneously, provide a resist underlayer having excellent coating properties, flattening properties, and gap-fill characteristics, and improved crosslinking characteristics. Accordingly, the resist underlayer composition according to an embodiment or the resist underlayer formed thereof may be advantageously used to form a fine pattern of a photoresist by using a high energy light source such as EUV and the like.

### DESCRIPTION OF THE DRAWINGS

FIGS. 1 to 5 are cross-sectional views illustrating a method of forming patterns using a resist underlayer composition according to an embodiment.

### BEST MODE

Example embodiments of the present disclosure will hereinafter be described in more detail, and may be easily practiced by a person skilled in the art. However, this disclosure may be embodied in many different forms and is not construed as limited to the example embodiments set forth herein.

In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, “substituted” refers to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, “hetero” refers to the inclusion of 1 to 10 heteroatoms selected from N, O, S, and P.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In addition, unless otherwise defined in the specification, “*” indicates a linking point of a structural unit or a moiety of a compound.

Hereinafter, a resist underlayer composition according to an embodiment is described.

The present invention provides a resist underlayer composition that may reduce a collapse of a resist pattern during a process of forming a fine pattern in photolithography using a short wavelength light source such as an ArF excimer laser (a wavelength of 193 nm) or a high energy ray such as EUV (extreme ultraviolet; a wavelength of 13.5 nm), shorten an etching process time since it is applied with an ultra-thin film, and improve crosslinking properties, thereby improving coating uniformity, gap-fill characteristics, and surface characteristics of the resist film, and a method of forming a photoresist pattern using the underlayer.

Specifically, the resist underlayer composition according to an embodiment includes a polymer including a cyanurate backbone or a triazine backbone in a main chain, side chain, or both main chain and side chain thereof, a compound represented by Chemical Formula 1, and a solvent.

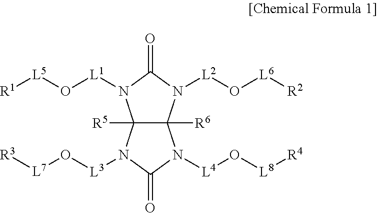

In Chemical Formula 1,
L¹ to L⁴, and L⁵ to L⁸ are each independently a single bond, a substituted or unsubstituted C1 to C10 alkylene group, a substituted or unsubstituted C3 to C20 cycloalkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, a halogen, a cyano group, an amino group, an epoxy group, a C1 to C10 alkoxy group, or a combination thereof, n and m are each independently an integer of 0 to 5, and * is a linking point), or a combination thereof,
R¹ to R⁴ are each independently a substituted or unsubstituted C1 to C10 aliphatic saturated or unsaturated hydrocarbon group, a substituted or unsubstituted C3 to C10 alicyclic saturated or unsaturated hydrocarbon group, a substituted or unsubstituted C2 to C10 saturated or unsaturated alicyclic heterohydrocarbon group, a substituted or unsubstituted C6 to C30 aromatic group, a substituted or unsubstituted C2 to C30 heteroaromatic group, a substituted or unsubstituted C1 to C10alkoxy group, or a combination thereof,
when L⁵ to L⁸ are all single bonds or are all unsubstituted C1 to C10 alkylene groups, R¹ to R⁴ are all substituted or unsubstituted C1 to C10 aliphatic saturated or unsaturated hydrocarbon groups, or R¹ to R⁴ are not all substituted or an unsubstituted C1 to C2 alkoxy group, and
R⁵ to R⁶ are each independently hydrogen, deuterium, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10heteroalkynyl group, or a combination thereof.

When the composition according to an embodiment is coated to form a film under a photoresist, this film may exhibit improved close contacting properties with the photoresist and thus prevent resist patterns from collapsing even during the fine patterning process, and in addition, crosslinking characteristics of the resist underlayer composition may be adjusted to improve coating uniformity, gap-fill, and pattern formality of the resist. In addition, the composition may be used to form an underlayer as an ultra-thin film and thus have an advantage of shortening an etching process time.

The compound represented by Chemical Formula 1 included in the composition includes oxygen and nitrogen included in a glycoluril core and four oxygens linked to each nitrogen atom of the glycoluril core and thus is rich in unshared electron pairs in molecules, wherein the four oxygens connected to the nitrogen atom may work as crosslinking sites with other compounds or functional groups. Accordingly, the compound represented by Chemical Formula 1 may serve to crosslink the polymers in the composition according to an embodiment and thus form a film formed of the composition to have a denser structure, resultantly, improving close contacting properties with the photoresist and preventing collapse of a resist pattern even during the fine patterning process.

Furthermore, a saturated or unsaturated aliphatic hydrocarbon group, a saturated or unsaturated alicyclic hydrocarbon group, a saturated or unsaturated alicyclic heterohydrocarbon group, an aromatic group, a heteroaromatic group, and the like bonded to the oxygen may impart hydrophobic properties to the compound and thus improve coating properties of the composition including the same and increase an etch rate thereof.

In an embodiment, in Chemical Formula 1, L¹ to L⁴, and L⁵ to L⁸ may each independently be a single bond, a substituted or unsubstituted C1 to C10 alkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, or a combination thereof, n and m are each independently an integer of 0 to 3, and * is a linking point), or a combination thereof,
R¹ to R⁴ may each independently be a substituted or unsubstituted C1 to C10 alkyl group, a substituted or unsubstituted C2 to C10 alkenyl group including at least one double bond, a substituted or unsubstituted C3 to C10 cycloalkyl group, a substituted or unsubstituted C1 to C10 alkoxy group, or a combination thereof, and
R⁵ to R⁶ may each independently be hydrogen, deuterium, a substituted or unsubstituted C1 to C10 alkyl group, a substituted or unsubstituted C2 to C10 alkenyl group, a vinyl group, an allyl group, a substituted or unsubstituted C1 to C10 heteroalkyl group, a substituted or unsubstituted C1 to C10 heteroalkenyl group, or a combination thereof.

Specifically, in Chemical Formula 1, L¹ to L⁴ may each independently be a substituted or unsubstituted C1 to C10 alkylene group, L⁵ to L⁸ may each independently be a single bond, a substituted or unsubstituted C1 to C10 alkylene group, *—(CRR′)n-O—(CR″R′″)m-*, *—CRR′—C(═O)—* (wherein, R, R′, R″, and R′″ are each independently hydrogen, deuterium, or a C1 to C10 alkyl group, n and m are each independently an integer of 0 to 2, and * is a linking point), or a combination thereof,
R¹ to R⁴ may each independently be a C1 to C10 alkyl group, a substituted or unsubstituted C2 to C10 alkenyl group including one double bond at the terminal end, C3 to C6 cycloalkyl group, a substituted or unsubstituted C1 to C6 alkoxy group, or a combination thereof, and
R⁵ to R⁶ may each independently be hydrogen, deuterium, a substituted or unsubstituted C1 to C10 alkyl group, a substituted or unsubstituted C2 to C5 alkenyl group, a vinyl group, an allyl group, a substituted or unsubstituted C1 to C5 heteroalkyl group, or a combination thereof.

For example, in Chemical Formula 1, L¹ to L⁴ may each independently be a C1 to C4 alkylene group, L⁵ to L⁸ may each independently be a single bond, a substituted or unsubstituted C1 to C4 alkylene group, *—(CRR′)n-O—(CR″R′″)m-*, *—CRR′—C(═O)—* (wherein, R, R′, R″, and R′″ are each independently hydrogen, deuterium, a C1 to C4 alkyl group, n and m are each independently an integer of 0 to 2, and * is a linking point), or a combination thereof,
R¹ to R⁴ may each independently be a C1 to C6 alkyl group, a substituted or unsubstituted C2 to C5 alkenyl group including one double bond at the terminal end, a C3 to C6 cycloalkyl group, a C1 to C6 alkoxy group, or a combination thereof, and
R⁵ to R⁶ may each independently be hydrogen, deuterium, a substituted or unsubstituted C1 to C6 alkyl group, a substituted or unsubstituted C1 to C5 heteroalkyl group, or a combination thereof, for example, hydrogen or a methyl group.

In Chemical Formula 1, when L¹ to L⁴ are each independently a C1 to C4 alkylene group, and at least one of L⁵ to L⁸ is a single bond, a group other than the single bond among L⁵ to L⁸ is *—(CRR′)n-O—(CR″R′″)m-* or *—CRR′-C(═O)—* (wherein R, R′, R″, and R′″ are each independently hydrogen, deuterium, a C1 to C4 alkyl group, n and m are each independently an integer of 0 to 2, and * is a linking point).

In Chemical Formula 1, when L¹ to L⁴ are all C1 to C4 alkylene groups, and L⁵ to L⁸ are all single bonds, R¹ to R⁴ may be all, each independently, a C3 to C6 cycloalkyl group, for example, a cyclohexyl group.

In an embodiment, L¹ to L⁴ in Chemical Formula 1 may be all methylene or ethylene groups, for example, methylene groups, and L⁵ to L⁸ may each be a single bond, or a group of *—CRR′—C(═O)—* or *—(CRR′)n-O—(CR″R′″)m-* (wherein R, R′, R″, and R′″ may each independently be hydrogen, a methyl group, or an ethyl group, n and m are each independently an integer of 0 to 1, and * is a linking point) may be a group, wherein R¹ to R⁴ are a methyl group, an ethyl group, a propyl group, a butyl group, a cyclohexyl group, an allyl group, a vinyl group, a C1 to C6 alkoxy group, or a combination thereof.

In the compound represented by Chemical Formula 1, when L¹ to L⁴ are all methylene groups, there is no case where L⁵ to L⁸ are all single bonds and R¹ to R⁴ are all unsubstituted alkyl groups, R¹ to R⁴ are all unsubstituted allyl groups, or R¹ to R⁴ are all unsubstituted alkoxy groups.

For example, the compound represented by Chemical Formula 1 may include at least one compound represented by Chemical Formulas 4 to 11.

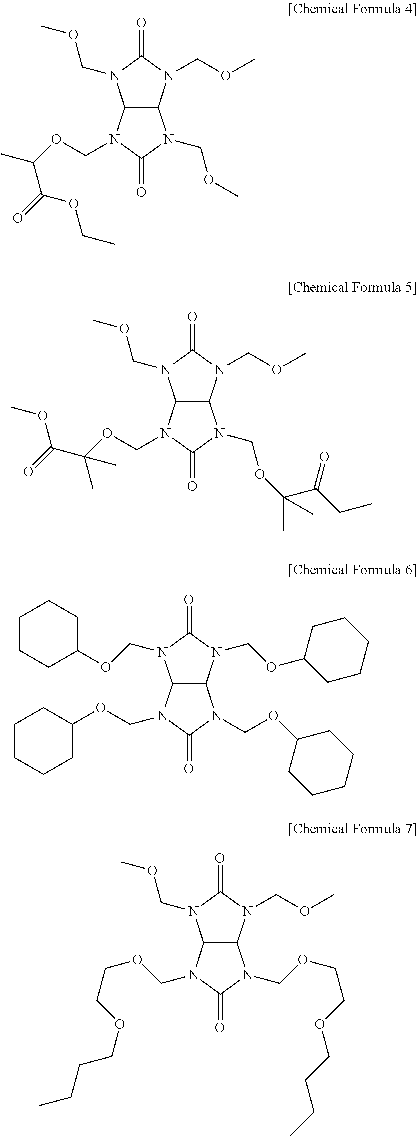

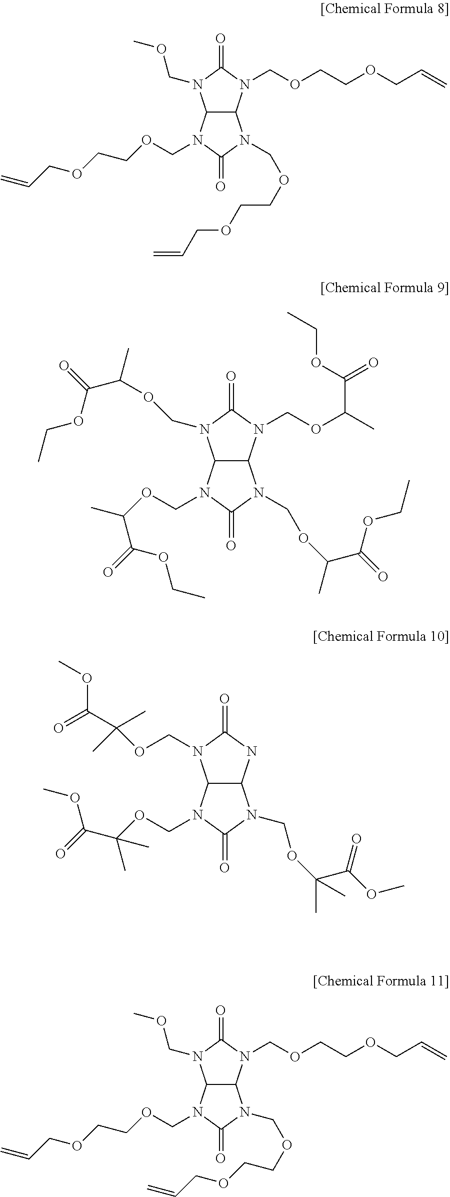

In the composition according to an embodiment, the polymer having the ring backbone including two or more nitrogen atoms in the ring may include at least one structure selected from Chemical Formulas A-1 to A-4, and specifically, in the main chain, the side chain, or both the main chain and the side chain:

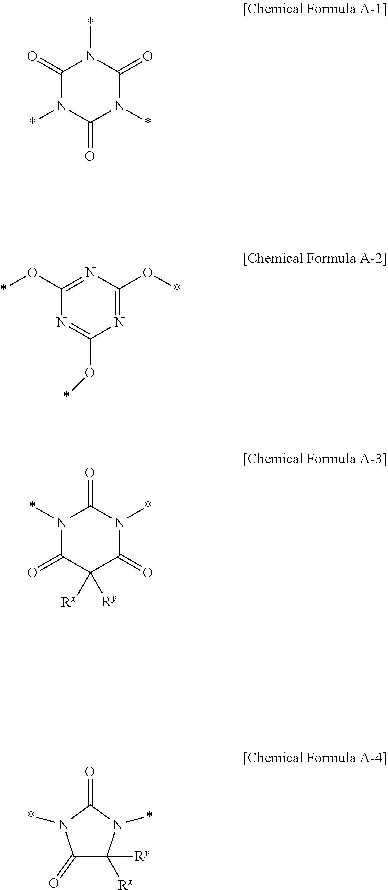

wherein, in Chemical Formulas A-1 to A-4,
R^{x} and R^{y} are each independently hydrogen, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
each * is a linking point in the polymer.

In the composition according to an embodiment, the polymer having the ring backbone including two or more nitrogen atoms in the ring may include a structural unit represented by Chemical Formula 2, a structural unit represented by Chemical Formula 3, or a combination thereof:

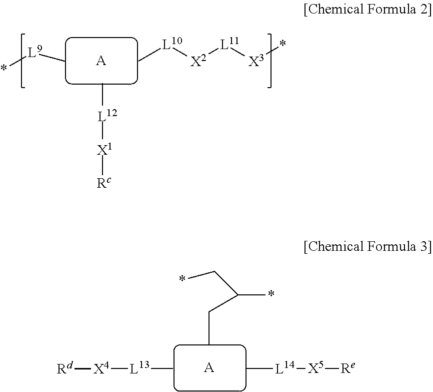

In Chemical Formulas 2 and 3,
A is a ring group including a cyanurate backbone or a triazine backbone,
R^{c}, R^{d}, and R^{e} are each independently a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof,
L⁹ to L¹⁴ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond, —O—, —S—, —S(═O)—, —S(═O)₂—, —C(═O)—, —(CO)O—, —O(CO)O—, —NR″″— (wherein, R“ ” is hydrogen, deuterium, or a C1 to C10 alkyl group), or a combination thereof, and
is a linking point to the main chain or terminal end group of the polymer, respectively.

A in Chemical Formulas 2 and 3 may be represented by at least one of Chemical Formulas A-1 to A-4:

The polymer may structurally include a ring backbone including two or more nitrogen atoms in a ring and thus improve an etch rate and coating properties of the resist underlayer film composition.

In addition, since the polymer is stable to an organic solvent and heat, when a resist underlayer is formed of the resist underlayer composition including the polymer, delamination of the resist underlayer and generation of by-products according to generation of chemical substances, etc. due to the solvent or the heat during the photoresist pattern-forming process, and also, thickness loss of the resist underlayer due to a solvent of the photoresist thereon may be minimized.

Accordingly, the resist underlayer composition according to an embodiment includes the compound represented by Chemical Formula 1 and thus exhibits improved crosslinking characteristics and in addition, includes the polymer and thus exhibits affinity with a solvent and thereby excellent coating properties and film formality, which bring about improved adherence to the resist thereon, and resultantly, may achieve excellent coating uniformity and gap-fill characteristics, and such a resist underlayer may also increase absorption efficiency with respect to an exposure light source and thus improve patterning performance.

In Chemical Formulas 2 and 3,
R^{c}, R^{d}, and R^{e} may each independently be a substituted or unsubstituted C1 to C10 alkyl group, a substituted or unsubstituted C1 to C10 heteroalkyl group, or a combination thereof,
L⁹ to L¹³ may each independently be a single bond, a substituted or unsubstituted C1 to C10 alkylene group, a substituted or unsubstituted C1 to C10 heteroalkylene group, or a combination thereof, and
X¹ to X⁵ may each independently be a single bond, —O—, —S—, or a combination thereof.

In Chemical Formulas 2 and 3,

R^{c}, R^{d}, and R^{e} may each independently be a C1 to C6 alkyl group unsubstituted or substituted with a hydroxyl group at the terminal end,

L⁹ to L¹³ may each independently be a single bond, a substituted or unsubstituted C1 to C6 alkylene group, or a combination thereof, and

X¹ to X⁵ may each independently be a single bond, or —S—.

The polymer may include any one of structural units represented by Chemical Formulas 12 to 21:

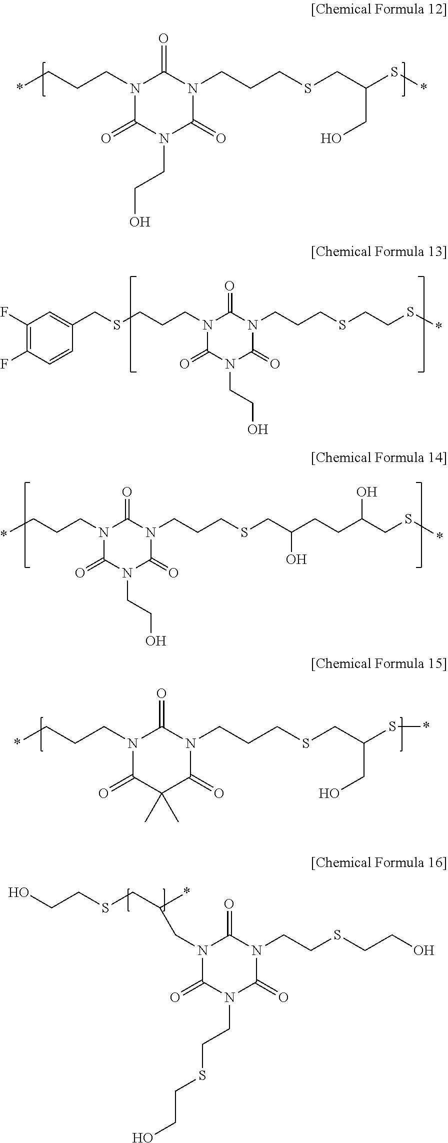

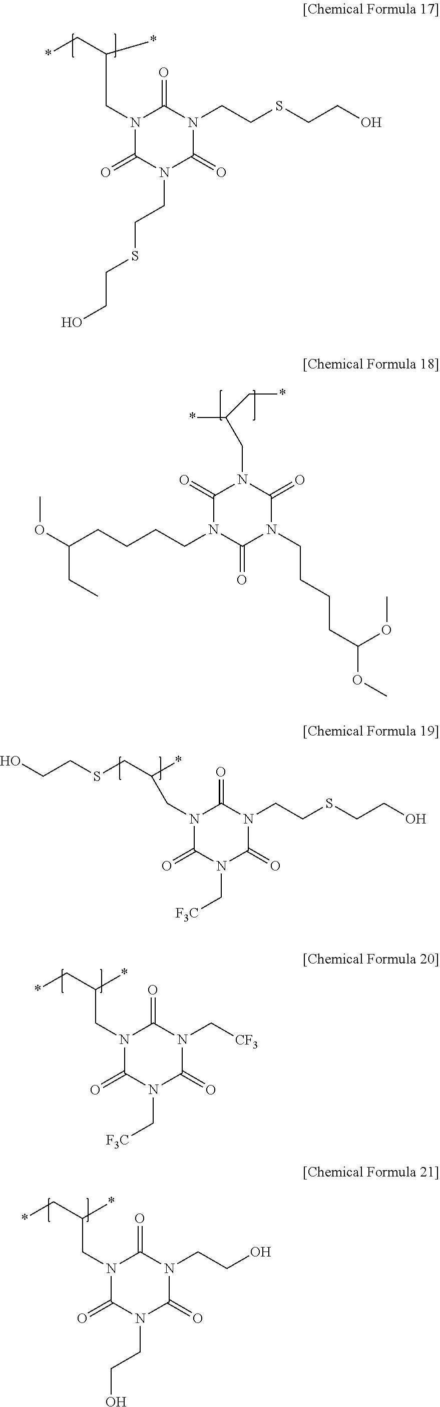

In Chemical Formulas 12 to 21,
is a linking point to the main chain, side chain, or terminal end group of the polymer.

The compound represented by Chemical Formula 1 may be included in an amount of 0.001 to 5 wt %, for example 0.01 wt % to 3 wt %, for example 0.01 wt % to 1 wt % based on the total weight of the resist underlayer composition. Within the above range, when forming the resist underlayer, a crosslinking rate may be controlled, and a thickness, surface roughness, and planarization degree of the resist underlayer may be controlled.

Meanwhile, the polymer may have a weight average molecular weight (Mw) of 2,000 g/mol to 300,000 g/mol. For example, the polymer may have a weight average molecular weight of 3,000 g/mol to 100,000 g/mol, or 3,000 g/mol to 50,000 g/mol. When the weight average molecular weight is within the above range, the carbon content and solubility in a solvent of the resist underlayer composition including the polymer may be adjusted and thus optimized.

The solvent is not particularly limited as long as it has sufficient solubility or dispersibility for the polymer, and may be, for example, propylene glycol, propylene glycol diacetate, propylene glycol methyl ether acetate, methoxy propanediol, diethylene glycol, diethylene glycol butylether, tri(ethylene glycol)monomethylether, propylene glycol monomethylether, propylene glycol monomethylether acetate, cyclohexanone, ethyl lactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

In addition, the resist underlayer composition may further include at least one other polymer among an acrylic resin, an epoxy resin, a novolac resin, a glycoluril resin, and a melamine resin, in addition to the polymers described above, but is limited thereto.

The resist underlayer composition may further include an additive of a surfactant, a thermal acid generator, a photoacid generator, a plasticizer, or a combination thereof.

The surfactant may be used to improve coating defects caused by an increase in a solid content when forming the resist underlayer, and may be, for example, an alkylbenzenesulfonate salt, an alkylpyridinium salt, polyethylene glycol, a quaternary ammonium salt, or the like, but is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzointosylate, 2-nitrobenzyltosylate, and other organic sulfonic acid alkylester may be used, but is not limited thereto.

The plasticizer is not particularly limited, and a variety of known plasticizers may be used. Examples of a plasticizer may include low molecular compounds such as phthalic acid esters, adipic acid esters, phosphoric acid esters, trimellitic acid esters, citric acid esters, and the like, polyether compounds, polyester-based compounds, polyacetal compounds, and the like.

The additive may be included in an amount of 0.0001 to 40 parts by weight based on 100 parts by weight of the resist underlayer composition. Within the ranges, solubility may be improved while optical properties of the resist underlayer composition are not changed.

According to another embodiment, a resist underlayer manufactured using the aforementioned resist underlayer composition is provided. The resist underlayer may be formed by coating the aforementioned resist underlayer composition on, for example, a substrate and then curing through a heat treatment process.

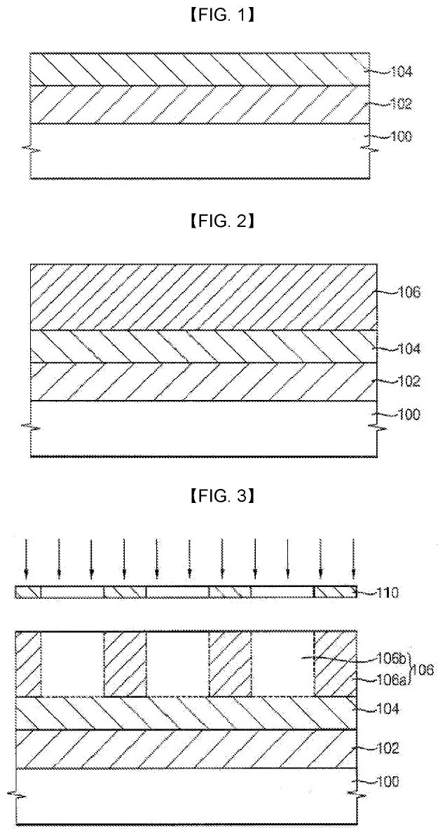

Hereinafter, a method of forming a pattern using the aforementioned resist underlayer composition is described with reference to FIGS. 1 to 5.

FIGS. 1 to 5 are cross-sectional views illustrating a method of forming a pattern using the resist underlayer composition according to the present invention.

Referring to FIG. 1, an etching target is prepared. The etching target may be a thin film 102 formed on a semiconductor substrate 100. Hereinafter, the etching target is limited to the thin film 102. An entire surface of the thin film 102 is washed to remove impurities and the like remaining thereon. The thin film 102 may be for example a silicon nitride layer, a polysilicon layer, or a silicon oxide layer.

Subsequently, the resist underlayer composition including the polymer having moieties represented by Chemical Formulas 1 and 2 and the solvent is coated on the surface of the cleaned thin film 102 by applying a spin coating method.

Then, the coated composition is dried and baked to form a resist underlayer 104 on the thin film 102. The baking may be performed at 100° C. to 500° C., for example 100° C. to 300° C. Specifically, the resist underlayer composition is described above in detail and thus will be omitted.

Referring to FIG. 2, a photoresist layer 106 is formed by coating a photoresist on the resist underlayer 104.

Examples of the photoresist may be a positive-type photoresist containing a naphthoquinonediazide compound and a novolac resin, a chemically-amplified positive photoresist containing an acid generator capable of dissociating acid through exposure, a compound decomposed under presence of the acid and having increased dissolubility in an alkali aqueous solution, and an alkali soluble resin, a chemically-amplified positive-type photoresist containing an alkali-soluble resin capable of applying a resin increasing dissolubility in an alkali aqueous solution, and the like.

Then, a substrate 100 having the photoresist layer 106 is primarily baked. The primary baking may be performed at 90° C. to 120° C.

Referring to FIG. 3, the photoresist layer 106 may be selectively exposed.

Exposure of the photoresist layer 106 may be for example performed by positioning an exposure mask having a predetermined pattern on a mask stage of an exposure apparatus and aligning the exposure mask 110 on the photoresist layer 106. Subsequently, a predetermined region of the photoresist layer 106 formed on the substrate 100 selectively reacts with light passing the exposure mask by radiating light into the exposure mask 110.

For example, the light used during the exposure may include short wavelength light such as an i-line having a wavelength of 365 nm, a KrF excimer laser having a wavelength of 248 nm, and an ArF excimer laser having a wavelength of 193 nm. In addition, EUV (extreme ultraviolet) having a wavelength of 13.5 nm corresponding to extreme ultraviolet light may be used.

The photoresist layer 106b of the exposed region has a relatively hydrophilicity compared with the photoresist layer 106a of the unexposed region. Accordingly, the exposed region 106b and non-exposed region 106a of the photoresist layer may have different solubility each other.

Subsequently, the substrate 100 is secondarily baked. The secondary baking may be performed at 90° C. to 150° C. The exposed region of the photoresist layer becomes easily dissoluble about a predetermined solvent due to the secondary baking.

Referring to FIG. 4, the exposed region of the photoresist layer 106b is dissolved and removed by a developing solution to form a photoresist pattern 108. Specifically, the exposed region 106b of the photoresist layer is dissolved and removed by using a developing solution such as tetra-methyl ammonium hydroxide (TMAH) and the like to finish the photoresist pattern 108.

Subsequently, the photoresist pattern 108 is used as an etching mask to etch the resist underlayer 104. Through the etching, an organic layer pattern 112 is formed. The etching may be for example dry etching using etching gas, and the etching gas may be for example CHF₃, CF₄, Cl₂, O₂, and a mixed gas thereof. As described above, since the resist underlayer formed by the resist underlayer composition according to the embodiment has a fast etch rate, a smooth etching process may be performed within a short time.

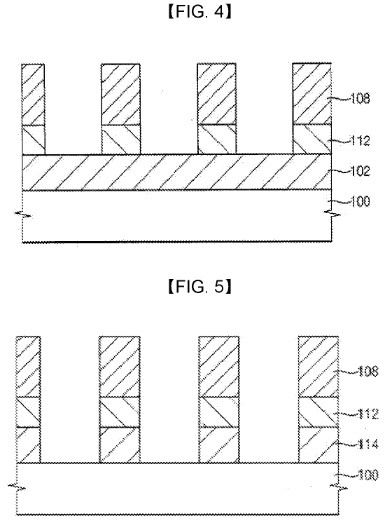

Referring to FIG. 5, the photoresist pattern 108 is applied as an etching mask to etch the exposed thin film 102. As a result, the thin film is formed into a thin film pattern 114. In the exposure process performed previously, a thin film pattern 114 formed by an exposure process performed using a short wavelength light source such as an i-line (a wavelength of 365 nm), a KrF excimer laser (a wavelength of 248 nm), and an ArF excimer laser (a wavelength of 193 nm) may have a width of tens to hundreds of nm, and the thin film pattern 114 formed by the exposure process performed using the EUV light source may have a width of less than or equal to about 20 nm.

Hereinafter, the present disclosure is described in more detail through Examples regarding synthesis of the polymer and preparation of a resist underlayer composition including the same. However, the present disclosure is technically not restricted by the following examples.

### Synthesis Examples

### Synthesis Example 1

1 g of p-toluene sulfonic acid (PTSA), 30 g of 1,3,4,6-tetrakis(methoxymethyl)glycoluril (TMGU), and 300 g of ethyl lactate were placed in a 500 mL 2-necked round-bottomed flask connected with a condenser and then, reacted at 80° C. for 10 hours. After the reaction proceeded, the reaction solution was cooled to room temperature. After concentrating a portion of the solvent from the reaction solution with an evaporator, PTSA was removed by twice working up with ethyl acetate/DIW. When the working-up was completed, the resultant was column-purified, finally obtaining a compound represented by Chemical Formula 4.

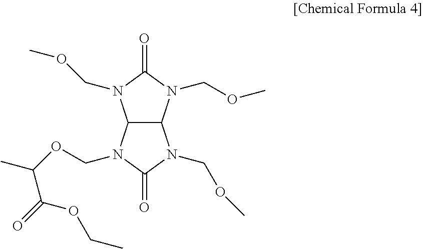 [SMILES: CCOC(=O)C(C)OCN1C(=O)N(COC)C2C1N(COC)C(=O)N2COC]

### Synthesis Example 2

A compound represented by Chemical Formula 5 was obtained in the same manner as Synthesis Example 1 except that methyl 2-hydroxy-2-methylpropanoate was used instead of the ethyl lactate.

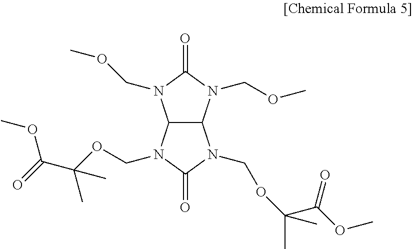

### Synthesis Example 3

A compound represented by Chemical Formula 6 was obtained in the same manner as Synthesis Example 1 except that cyclohexanol was used instead of the ethyl lactate.

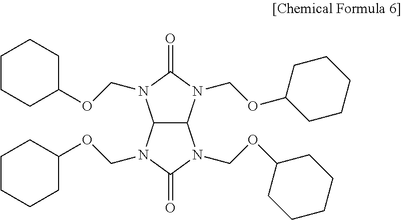 [SMILES: O=C1N(COC2CCCCC2)C2C(N1COC1CCCCC1)N(COC1CCCCC1)C(=O)N2COC1CCCCC1]

### Synthesis Example 4

A compound represented by Chemical Formula 7 was obtained in the same manner as Synthesis Example 1 except that ethylene glycol butyl ether was used instead of the ethyl lactate.

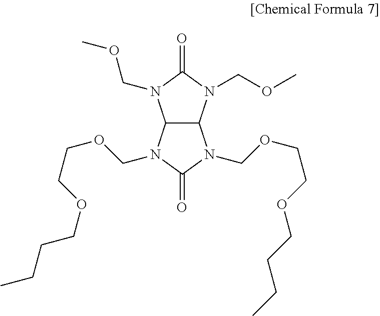 [SMILES: CCCCOCCOCN1C(=O)N(COCCOCCCC)C2C1N(COC)C(=O)N2COC]

### Synthesis Example 5

A compound represented by Chemical Formula 8 was obtained in the same manner as Synthesis Example 1 except that 2-allyloxyethanol was used instead of the ethyl lactate.

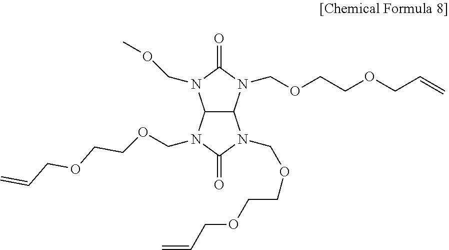 [SMILES: C=CCOCCOCN1C(=O)N(COCCOCC=C)C2C1N(COC)C(=O)N2COCCOCC=C]

### Synthesis Example 6

20 g of 1,3-diallyl-5-(2-hydroxyethyl)-isocyanurate, 7.9 g of 2,3-dimercapto-1-propanol, 1 g of azobisisobutyronitrile (AIBN), and 50 g of N,N-dimethyl formamide were placed in a 250 mL four-necked flask to prepare a reaction solution, and a condenser was connected thereto. The reaction solution was heated for a reaction at 50° C. for 5 hours and then, cooled to room temperature. Subsequently, the reaction solution was added dropwise to a beaker containing 300 g of distilled water, while stirred, to produce gum and then, dissolved in 30 g of tetrahydrofuran (THF). The dissolved resin solution was treated with toluene to form precipitates and remove single and low molecules, finally obtaining a polymer (Mw=3,700 g/mol) having a structural unit represented by Chemical Formula 12.

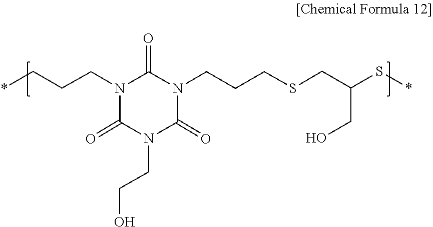

### Synthesis Example 7

25 g of triallyl isocyanurate and 12 g of 2-mercapto-1-ethanol, 0.7 g of AIBN, and 55 g of N,N-dimethyl formamide were placed in a 250 mL four-necked flask to prepare a reaction solution, and a condenser was connected thereto. The reaction solution was heated for a reaction at 80° C. for 10 hours and cooled to room temperature. Subsequently, the reaction solution was added dropwise to a beaker containing 300 g of distilled water, while stirred, to produce gum and then, dissolved in 50 g of tetrahydrofuran (THF). The dissolved resin solution was treated with toluene to form precipitates and remove single and low molecules, finally obtaining a polymer (Mw=13,200 g/mol) having a structural unit represented by Chemical Formula 16.

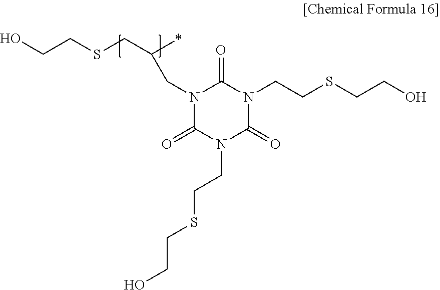

### Preparation of Resist Underlaver Composition

### Example 1

A resist underlayer composition was prepared in a method of completely dissolving 1 g of the polymer according to Synthesis Example 7, 0.2 g of the compound according to Synthesis Example 1, and 0.02 g of pyridinium p-toluenesulfonate in 120 g of propylene glycol methyl ether (PGME).

### Example 2

A resist underlayer composition was prepared in a method of completely dissolving 1 g of the polymer according to Synthesis Example 7, 0.2 g of the compound according to Synthesis Example 2, and 0.02 g of pyridinium p-toluenesulfonate in 120 g of propylene glycol methyl ether (PGME).

### Example 3

A resist underlayer composition was prepared in a method of completely dissolving 1 g of the polymer according to Synthesis Example 7, 0.2 g of the compound according to Synthesis Example 3, and 0.02 g of pyridinium p-toluenesulfonate in 120 g of propylene glycol methyl ether (PGME).

### Example 4

A resist underlayer composition was prepared in a method of completely dissolving 1 g of the polymer according to Synthesis Example 6, 0.1 g of the compound according to Synthesis Example 1, 0.1 g of the compound according to Synthesis Example 4, and 0.02 g of pyridinium p-toluenesulfonate in 120 g of a mixed solvent of propylene glycol methyl ether (PGME) and ethyl lactate (EL) (in a mixing volume ratio=1:1).

### Example 5

A resist underlayer composition was prepared in a method of completely dissolving 1 g of the polymer according to Synthesis Example 6, 0.2 g of the compound according to Synthesis Example 2, 0.1 g of the compound represented by Synthesis Example 5, and 0.02 g of pyridinium p-toluenesulfonate in 120 g of a mixed solvent of propylene glycol methyl ether (PGME) and ethyl lactate (EL) (in a mixing volume ratio=1:1).

### Example 6

A resist underlayer composition was prepared in a method of completely dissolving 1 g of the polymer according to Synthesis Example 6, 0.3 g of the compound according to Synthesis Example 2, and 0.02 g of pyridinium p-toluenesulfonate in 120 g of a mixed solvent of propylene glycol methyl ether (PGME) and ethyl lactate (EL) (in a mixing volume ratio=1:1).

### Comparative Example 1

A resist underlayer composition was prepared in a method of completely dissolving 1 g of the polymer according to Synthesis Example 6, 0.2 g of a compound represented by Chemical Formula 22 (2,4,6-tris[bis(methoxymethyl)amino]-1,3,5-triazine; TCI (Tokyo Chemical Industry)), 2 g of hexamethoxy methylmelamine (TCI), and 0.02 g of pyridinium p-toluenesulfonate in 120 g of a mixed solvent of propylene glycol methyl ether (PGME) and ethyl lactate (EL) (in a mixing volume ratio=1:1).

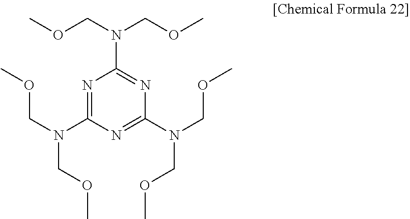

### Comparative Example 2

A resist underlayer composition was prepared in a method of completely dissolving 1 g of the polymer according to Synthesis Example 7, 0.2 g of a compound represented by Chemical Formula 23 (3,3′, 5,5′-tetrakis(methoxymethyl)[1,1′-biphenyl]-4,4′-diol; Merch KGaA), and 0.02 g of pyridinium p-toluenesulfonate in 120 g of a mixed solvent of propylene glycol methyl ether (PGME) and ethyl lactate (EL) (a mixing volume ratio=1:1).

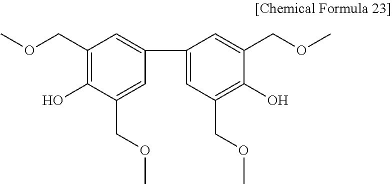

### Evaluation of Coating Uniformity

The compositions according to Example 1 to 6 and Comparative Example 2 were respectively taken by 2 ml and then, spin-coated on an 8-inch wafer with an auto track (ACT-8, TEL (Tokyo Electron Limited)) at 1,500 rpm for seconds and then, cured at 210° C. for 90 seconds to form 50 Å-thick ultra-thin films.

Coating uniformity was evaluated by measuring a thickness at 51 points on the horizontal axis, and the results are shown in Table 1. Then, a difference (Å) between a maximum value and a minimum value among thickness measurements at 51 points was obtained to evaluate the coating uniformity, and herein, as the difference was smaller, the coating uniformity was more improved.

TABLE 1

| | Coating uniformity @ 50 Å film |
|---|---|
| | (maximum value − minimum value (Å)) |
| Example 1 | 1.2 |
| Example 2 | 0.9 |
| Example 3 | 0.7 |
| Example 4 | 0.9 |
| Example 5 | 0.5 |
| Example 6 | 2.8 |
| Comparative Example 2 | 5.6 |

Referring to Table 1, the resist underlayer compositions according to Examples 1 to 6 exhibited coating uniformity that is equal to or greater than the resist underlayer composition according to Comparative Example 2.

### Evaluation of Gas Generation Amount

Each composition according Examples 1 to 6 and Comparative Example 1 was taken by 2 mL and then, coated on a 4 inch wafer at 1,500 rpm for 20 seconds with a spin-coater (Mikasa Co., Ltd.). The coated composition was baked at 130° C. for 2 minutes to remove a residual solvent and cured at 210° C. for 5 minutes, and an amount of gas generated therefrom was measured by using a QCM equipment during the curing. The measured amount of gas was provided as a relative value based on that of Example 1 as shown in Table 2, wherein a larger number indicates a larger gas generation amount.

TABLE 2

| | Gas generation amount |
|---|---|
| Example 1 | 1 |
| Example 2 | 0.95 |
| Example 3 | 1.13 |
| Example 4 | 0.89 |
| Example 5 | 0.93 |
| Example 6 | 0.85 |
| Comparative Example 1 | 1.59 |

As provided in Table 2, the embodiments of the present invention exhibited a small gas generation amount, compared with the comparative example.

### Evaluation of Gap-Fill Characteristics

On a wafer patterned to have each line width of lines and spaces of 150 nm and 60 nm and a height of 220 nm, the resist underlayer compositions according to Example 3 to 6 and Comparative Examples 1 to 2 were respectively coated to be 250 nm thick with a spin coater and then, heated at 120° C. for 50 seconds and at 250° C. for 1 minute by using a hot plate, forming resist underlayers. The formed resist underlayers were examined with respect to the cross-sections by using FE-SEM (Field Emission Scanning Electron Microscope, S-4300, Hitachi Ltd.), and when a thickness difference between high portion (line portion) and low portion (space portion) was less than 3 nm, “Very good” was given, when the difference was 3 nm to 10 nm, “Good” was given, and when the difference was greater than 10 nm, “Inferior” was given, and the results are shown in Table 3.

TABLE 3

| | Gap-fill characteristics |
|---|---|
| Example 3 | Very good |
| Example 4 | Good |
| Example 5 | Very good |
| Example 6 | Very good |
| Comparative Example 1 | Inferior |
| Comparative Example 2 | Inferior |

Hereinbefore, the certain embodiments of the present invention have been described and illustrated, however, it is apparent to a person with ordinary skill in the art that the present invention is not limited to the embodiment as described, and may be variously modified and transformed without departing from the spirit and scope of the present invention. Accordingly, the modified or transformed embodiments as such may not be understood separately from the technical ideas and aspects of the present invention, and the modified embodiments are within the scope of the claims of the present invention.

<Description of Symbols>

| | |
|---|---|
| 100: substrate | 102: thin film |
| 104: resist underlayer | 106: photoresist layer |
| 108: photoresist pattern | 110: mask |
| 112: organic layer pattern | 114: thin film pattern |

1. A resist underlayer composition, comprising
a polymer having a ring backbone including two or more nitrogen atoms in a ring,
a compound represented by Chemical Formula 1, and
a solvent: 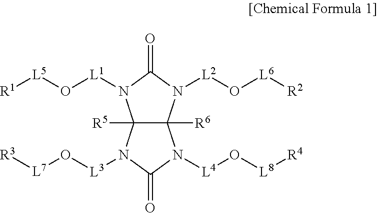
wherein, in Chemical Formula 1,
L¹ to L⁴, and L⁵ to L⁸ are each independently a single bond, a substituted or unsubstituted C1 to C10 alkylene group, a substituted or unsubstituted C3 to C20 cycloalkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, a halogen, a cyano group, an amino group, an epoxy group, a C1 to C10 alkoxy group, or a combination thereof, n and m are each independently an integer of 0 to 5, and * is a linking point), or a combination thereof,
R¹ to R⁴ are each independently a substituted or unsubstituted C1 to C10 aliphatic saturated or unsaturated hydrocarbon group, a substituted or unsubstituted C3 to C10 alicyclic saturated or unsaturated hydrocarbon group, a substituted or unsubstituted C2 to C10 saturated or unsaturated alicyclic heterohydrocarbon group, a substituted or unsubstituted C6 to C30 aromatic group, a substituted or unsubstituted C2 to C30 heteroaromatic group, a substituted or unsubstituted C1 to C10 alkoxy group, or a combination thereof,
when L⁵ to L⁸ are all single bonds or are all unsubstituted C1 to C10 alkylene groups, R¹ to R⁴ are all substituted or unsubstituted C1 to C10 aliphatic saturated or unsaturated hydrocarbon groups, or R¹ to R⁴ are not all substituted or an unsubstituted C1 to C2 alkoxy group, and
R⁵ to R⁶ are each independently hydrogen, deuterium, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, or a combination thereof.

2. The resist underlayer composition of claim 1, wherein in Chemical Formula 1, L¹ to L⁴, and L⁵ to L⁸ are each independently a single bond, a substituted or unsubstituted C1 to C10 alkylene group, *—(CRR′)n-O—(CR″R′″)m-*, *—CRR′—C(═O)—* (wherein, R, R′, R″, and R′″ are each independently hydrogen, deuterium, a C1 to C10 alkyl group, a C3 to C6 cycloalkyl group, or a combination thereof, n and m are each independently an integer of 0 to 3, and * is a linking point), or a combination thereof, and
R¹ to R⁴ are each independently a substituted or unsubstituted C1 to C10 alkyl group, a substituted or unsubstituted C2 to C10 alkenyl group including at least one double bond, a substituted or unsubstituted C3 to C10 cycloalkyl group, a substituted or unsubstituted C1 to C10 alkoxy group, or a combination thereof.

3. The resist underlayer composition of claim 1, wherein the compound represented by Chemical Formula 1 comprises at least one of compounds represented by Chemical Formulas 4 to 11:

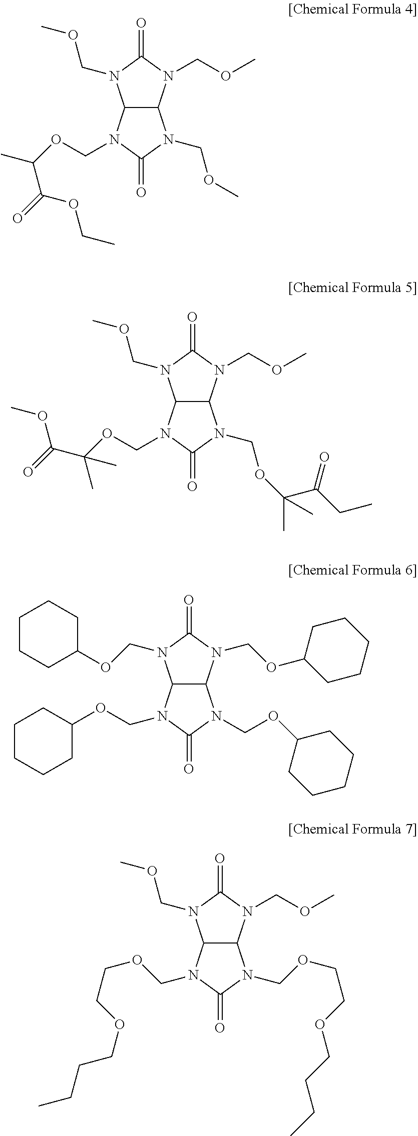

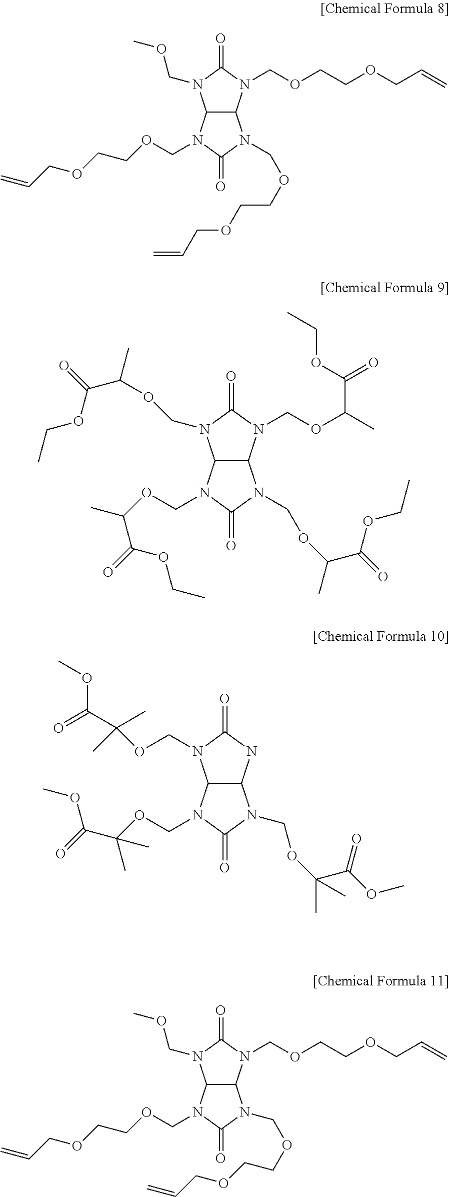

4. The resist underlayer composition of claim 1, wherein the polymer having the ring backbone including two or more nitrogen atoms in the ring is represented by at least one of structures represented by Chemical Formulas A-1 to A-4: 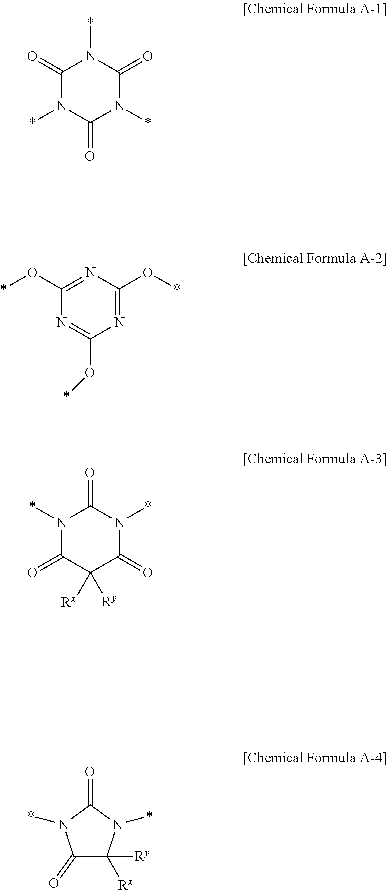
wherein, in Chemical Formulas A-1 to A-4,
R^{x} and R^{y} are each independently hydrogen, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof,
each * is a linking point in the polymer.

5. The resist underlayer composition of claim 1, wherein the polymer comprises a structural unit represented by Chemical Formula 2, a structural unit represented by Chemical Formula 3, or a combination thereof: 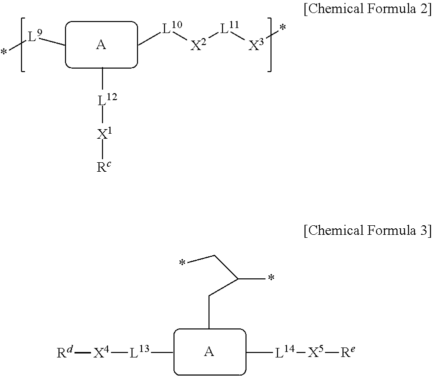
wherein, in Chemical Formulas 2 and 3,
A is a ring group including two or more nitrogen atoms in the ring,
R^{c}, R^{d}, and R^{e} are each independently a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof;
L⁹ to L¹⁴ are each independently a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C1 to C20 heteroarylene group, or a combination thereof,
X¹ to X⁵ are each independently a single bond, —O—, —S—, —S(═O)—, —S(═O)₂—, —C(═O)—, —(CO)O—, —O(CO)O—, —NR″ (wherein, R″″ is hydrogen, deuterium, or a C1 to C10 alkyl group), or a combination thereof, and
* is a linking point to the main chain or terminal end group of the polymer, respectively.

6. The resist underlayer composition of claim 5, wherein in Chemical Formulas 2 and 3, R^{c}, R^{d}, and R^{e} are each independently a substituted or unsubstituted C1 to C10 alkyl group, a substituted or unsubstituted C1 to C10 heteroalkyl group, or a combination thereof,
in Chemical Formulas 2 and 3, L⁹ to L¹³ are each independently a single bond, a substituted or unsubstituted C1 to C10 alkylene group, a substituted or unsubstituted C1 to C10 heteroalkylene group, or a combination thereof, and
in Chemical Formulas 2 and 3, X¹ to X⁵ are each independently a single bond, —O—, —S—, or a combination thereof.

7. The resist underlayer composition of claim 5, wherein in Chemical Formulas 2 and 3, A is represented by at least one of Chemical Formulas A-1 to A-4, in Chemical Formulas A-1 and A-4,
* indicates a linking point to any one of L⁹ to L¹⁴ in Chemical Formulas 2 and 3, or a side chain of the polymer, respectively: 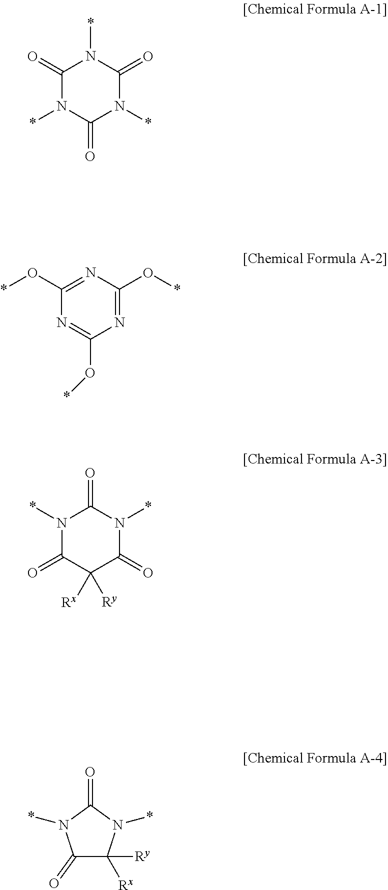
wherein, in Chemical Formulas A-1 to A-4,
R^{x} and R^{y} are each independently hydrogen, a substituted or unsubstituted C1 to C10 alkyl group, a substituted or unsubstituted C2 to C10 alkenyl group, a vinyl group, an allyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is each a linking point.

8. The resist underlayer composition of claim 1, wherein the polymer comprises any one of structural units represented by Chemical Formulas 12 to 21: 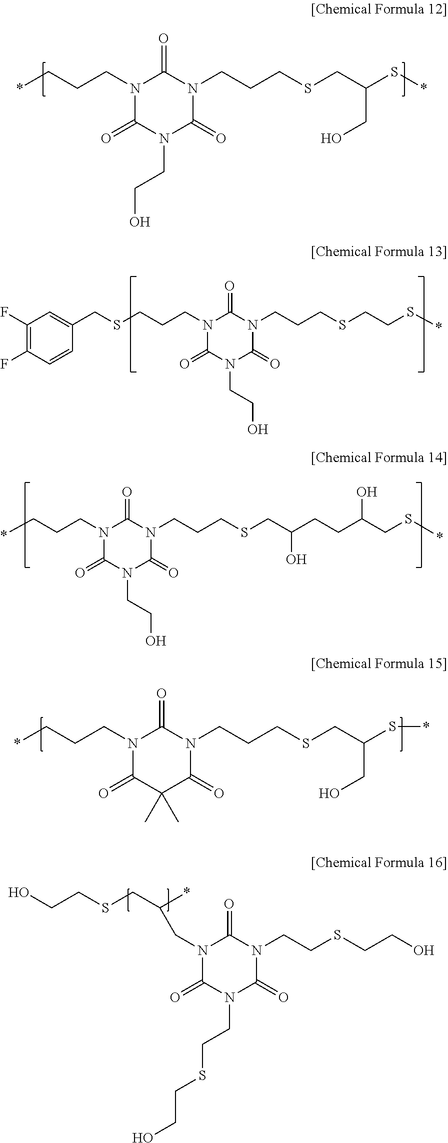 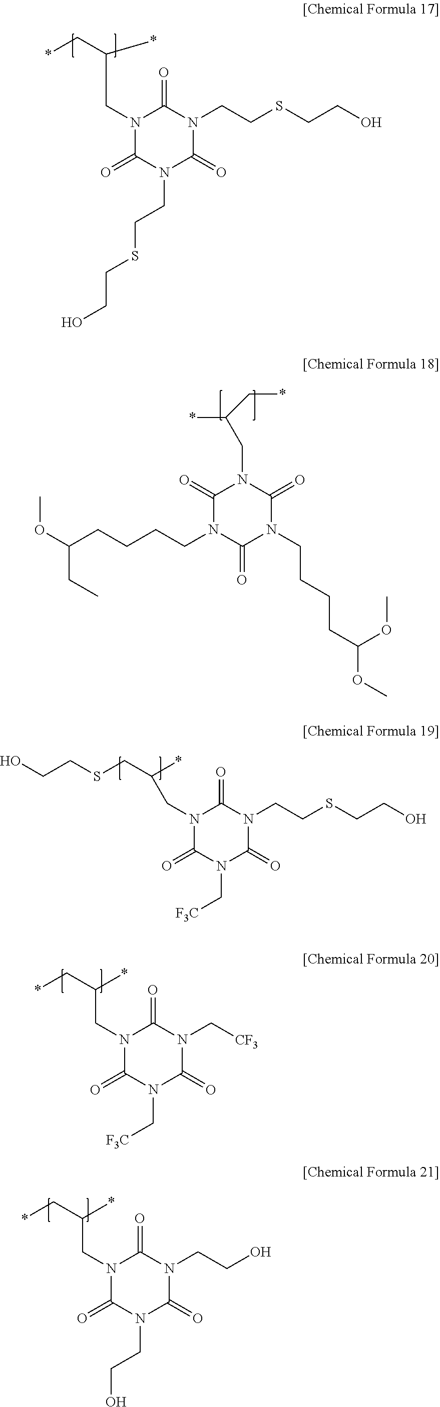
wherein, in Chemical Formulas 12 to 21,
* is a linking point to the main chain, side chain, or terminal end group of the polymer.

9. The resist underlayer composition of claim 1, wherein the compound represented by Chemical Formula 1 is included in an amount of 0.01 wt % to 5 wt % based on the total weight of the resist underlayer composition.

10. The resist underlayer composition of claim 1, wherein the polymer has a weight average molecular weight of 2,000 g/mol to 300,000 g/mol.

11. The resist underlayer composition of claim 1, wherein the resist underlayer composition further comprises one or more polymers selected from an acrylic resin, an epoxy resin, a novolac resin, a glycoluril resin, and a melamine resin.

12. The resist underlayer composition of claim 1, wherein the resist underlayer composition further comprises an additive of a surfactant, a thermal acid generator, a plasticizer, or a combination thereof.

13. A method of forming a pattern, comprising
forming an etching target layer on a substrate,
forming a resist underlayer by applying the resist underlayer composition of claim 1 on the etching target layer,
forming a photoresist pattern on the resist underlayer, and
sequentially etching the resist underlayer and the etching target layer using the photoresist pattern as an etching mask.

14. The method of claim 13, wherein
the forming of the photoresist pattern comprises
forming a photoresist layer on the resist underlayer,
exposing the photoresist layer, and
developing the photoresist layer.

15. The method of claim 13, wherein the forming of the resist underlayer comprises heat treatment at a temperature of 100° C. to 500° C. after coating the resist underlayer composition.
